(19) United States
(12) Patent Application Publication
(10) Pub. No.: US 2016/0003911 A1
(43) Pub. Date: Jan. 7, 2016

(54) BATTERY CELL CHARACTERISTIC IDENTIFICATION

(71) Applicant: Infineon Technologies AG, Neubiberg (DE)

(72) Inventors: Cheow Guan Lim, Singapore (SG); Chunyan Zhang, Singapore (SG); Tue Fatt David Wee, Singapore (SG); Tse Siang Gary Lim, Singapore (SG); Robert P. Rozario, San Jose, CA (US)

(21) Appl. No.: 14/323,307

(22) Filed: Jul. 3, 2014

(51) Int. Cl. G01R 31/36

(52) U.S. Cl. CPC G01R 31/3606; G01R 31/3658

(57) ABSTRACT

Devices, systems, and methods for battery monitoring are disclosed. An example method performs a first measurement on a battery cell installed in a location to determine a first charging capacity and determines a set of values for a permitted charging capacity trace region based on the first charging capacity and a number of charge/discharge cycles subsequent to performing the first measurement. The example method performs a second measurement on a battery cell installed in the location to determine a second charging capacity and compares the second charging capacity to the permitted charging capacity trace region and determines that the battery cell installed in the location at a time of the second measurement is not the same battery cell installed in the location at the time of the first measurement when the second charging capacity is not a value within the set of permitted values of the charging capacity trace region.

### TECHNICAL FIELD

This disclosure relates to batteries and more particular, to techniques and circuits associated with battery cell characteristic identification.

### BACKGROUND

Batteries may be used to power many different electrical or electronic devices. In some cases, the cost of such a battery may be a significant percentage of the overall cost of the electrical or electronic device. For example, the batteries used to power mobile phones and tablet computing devices may be a significant percentage of the cost of these systems, e.g., production costs, total costs to the retailer, or costs to the consumer.

Generally, the demand for batteries in a variety of areas has led to a market for recycling of batteries, or more specifically, recycling of circuitry in a battery system. For example, in some cases the battery system may include battery cells. These cells may be installed on a circuit board or printed wire board (PWB). The circuit board or PWB may also include battery support circuitry, such as circuitry that monitors the battery cells. Such circuitry may, for example, monitor the number of times the battery cells have been re-charged, e.g., using a counter.

In order to recycle the battery support circuitry and the circuit board, the battery cells may be removed so that new battery cells may be installed. While this may allow for the circuit board and battery related circuitry to be reused, the battery monitoring circuitry may become inaccurate after one or more new battery cells are attached to the circuit board because the reuse information may generally relate to the previous battery rather than the new battery cell or cells.

### SUMMARY

In general, techniques and circuits are described that may monitor a battery cell or battery cells in a battery system to determine if the battery cell or battery cells have been changed. In some examples, monitoring the battery cell or cells to determine if the battery cell or battery cells have been changed may be based on measurements of trailing charging capacity values. The test may be performed with the same test procedure to observe changes in charging capacity level. Furthermore the same test procedure may be performed across multiple cells, however, charging capacity levels will generally be compared for a given cell, or for a particular group of cells when data is stored on a group by group basis.

Generally, different cells may be at different points in the battery life cycle, such that different batteries may have different charging capacity values. This may be true even for the same type and model of battery cell. A system according to the techniques of this disclosure may, for example, determine that a cell with lower remaining capacity has been swapped for a cell that is inserted that has full capacity.

In some examples, the disclosure is directed to a method of battery monitoring including performing a first measurement on a battery cell installed in a location to determine a first charging capacity, determining a set of values for a permitted charging capacity trace region based on the first charging capacity and a number of charge/discharge cycles subsequent to performing the first measurement, performing a second measurement on a battery cell installed in the location to determine a second charging capacity, comparing the second charging capacity to the permitted charging capacity trace region, and determining that the battery cell installed in the location at a time of the second measurement is the same battery cell installed in the location at the time of the first measurement when the second charging capacity is a value within the set of values for a permitted charging capacity trace region and that the battery cell installed in the location at a time of the second measurement is not the same battery cell installed in the location at the time of the first measurement when the second charging capacity is not a value within the set of values for a permitted charging capacity trace region.

In an example, the disclosure is directed to a device for battery monitoring including a memory and a processor, coupled to the memory and configured to perform a first measurement on a battery cell installed in a location to determine an charging capacity, determine a set of values for a permitted charging capacity trace region based on the first charging capacity and a number of charge/discharge cycles subsequent to performing the first measurement, perform a second measurement on a battery cell installed in the location to determine a second charging capacity, compare the second charging capacity to the permitted charging capacity trace region, and determine that the battery cell installed in the location at a time of the second measurement is the same battery cell installed in the location at the time of the first measurement when the second charging capacity is a value within the s set of values for a permitted charging capacity trace region and that the battery cell installed in the location at the time of the second measurement is not the same battery cell installed in the location at the time of the first measurement when the second charging capacity is not a value within the set of values for a permitted charging capacity trace region.

In another example, the disclosure is directed to a device for battery monitoring including means for performing a first measurement on a battery cell installed in a location to determine an charging capacity, means for determining a set of values for a permitted charging capacity trace region based on the first charging capacity and a number of charge/discharge cycles subsequent to performing the first measurement, means for performing a second measurement on a battery cell installed in the location to determine a second charging capacity, means for comparing the second charging capacity to the permitted charging capacity trace region, and means for determining that the battery cell installed in the location at a time of the second measurement is the same battery cell installed in the location at the time of the first measurement when the second charging capacity is a value within the set of values for a permitted charging capacity trace region and that the battery cell installed in the location at the time of the second measurement is not the same battery cell installed in the location at the time of the first measurement when the second charging capacity is not a value within the set of values for a permitted charging capacity trace region.

The details of one or more examples are set forth in the accompanying drawings and the description below. Other features, objects, and advantages of the disclosure will be apparent from the description and drawings, and from the claims.

### BRIEF DESCRIPTION OF DRAWINGS

FIG. 1 is a block diagram illustrating different battery cell swapping tactics in accordance with one or more aspects of the present disclosure.

FIG. 2 is a graph illustrating an example of the trailing effect of capacity of a battery over a number of charging/discharging cycles in accordance with one or more aspects of the present disclosure.

FIG. 3 is a graph illustrating an example of battery cell capacity before and after a cell swap with a cell that is inserted that has full capacity in accordance with one or more aspects of the present disclosure.

FIG. 4 is a block diagram illustrating an example electronic device in accordance with one or more aspects of the present disclosure.

FIG. 5 is a flowchart illustrating an example method for detection of battery monitoring circuitry recycling, in accordance with one or more aspects of the present disclosure.

FIG. 6 is another flowchart illustrating an example method for detection of battery monitoring circuitry recycling, in accordance with one or more aspects of the present disclosure.

### DETAILED DESCRIPTION

In general, techniques and circuits are described that may monitor a battery cell or battery cells in a battery system to determine if the battery cell or battery cells have been changed. In some examples, monitoring the battery cell or cells to determine if the battery cell or battery cells have been changed may be based on measurements of trailing charging capacity, such as a trailing nominal full charging capacity (NFCC) values. The test may be performed with the same test procedure, and changes in charging capacity, such as changes in NFCC level may be measured by circuitry implementing the method. Changes in charging capacity, such as changes in NFCC may generally decrease over time for a given battery cell, while changes may be more abrupt when a battery cell is replaced with a different battery cell. Various exampled are described herein related to NFCC. It will be understood, however, that other measures of charging capacity may be used.

The battery monitoring circuitry may monitor one or more batteries or battery cells. In some examples, the battery monitoring circuitry may be part of a battery system, e.g., on a circuit board on which the battery cell or cells are installed. In other examples, the battery monitoring circuitry may be part of battery charging circuitry. In other examples, the battery monitoring circuitry may be part of a mobile electronic device being powered by the battery cell or battery cells being monitored. Additionally, in other examples, some combination of circuitry in the battery system, battery charging circuitry, and/or a mobile electronic device being powered by the battery cell or battery cells being monitored may be used to implement one or more aspects of the present disclosure.

Example battery monitoring circuitry may perform a first measurement on a battery cell installed in a location to determine a first nominal full charging capacity (NFCC). The example battery monitoring circuitry may determine a set of values for a permitted NFCC trace region based on the first NFCC and a number of charge/discharge cycles subsequent to performing the first measurement. The example battery monitoring circuitry may also perform a second measurement on a battery cell installed in the location to determine a second NFCC. The example battery monitoring circuitry may compare the second NFCC to the permitted NFCC trace region.

The example battery monitoring circuitry may determine that the battery cell installed in the location at a time of the second measurement is the same battery cell installed in the location at the time of the first measurement when the second NFCC is a value within the set of permitted values of the NFCC trace region and that the battery cell installed in the location at the time of the second measurement is not the same battery cell installed in the location at the time of the first measurement when the second NFCC is not a value within the set of permitted values of the NFCC trace region.

Some examples may use authentication and a counter to ensure the authenticity of the battery cell from the manufacturer. This may be used in conjunction with, for example, such applications as camera batteries, mobile handsets, and other battery powered electronic devices. However, in dealing with battery swapping, the use of authentication and a counter may be incomplete, e.g., when one battery cell is swapped for another battery cell. When an authentication chip on the battery circuitry is swapped to be reused with a new battery, there is currently no mechanism to detect such swapping. The authentication chip will authenticate the battery pack but will not be able to identify that a call has been replaced with a new cell. A counter that counts the usage of the battery and stops the usage of the battery when a certain count value is reach in an unidirectional manner limits the usage, however, when the battery has been swapped it may still be in good condition when the count value is reached.

Battery recycling may be common and may happen when refurbishing a battery. Such recycling may also occur with a newly manufactured battery. A battery cell of a newly manufactured battery may be swapped for an inferior battery. This may increase the risk of such a battery failing because the swapped battery cell may be battery cell of inferior quality when compared to the original battery cell and the inferior quality battery cell may pose a safety risk to the end user and a quality risk to the product.

If the swapped in cell is of smaller capacity, the battery may degrade faster during usage due to, for example, more frequent charging. Faster battery degrading may lead to an impact on the quality of the product. During charging under more harsh temperature condition, the charging current rating to a battery, even a new battery, may be decreased. A battery charged under more harsh temperature condition may lead to a final charging limit that may deteriorate the battery's solid-electro-interphase between the cathode and anode of the battery and self-deterioration may lead to combustion of the battery.

Different scenarios for swapping of a battery cell may be used. These different scenarios may be referred to as different levels. For example, a “basic level” scenario (or just basic level) may involve only swapping the battery pack on a printed wire board (PWB) that does not include an authentication feature, e.g., the circuitry on the PWB does not include circuitry to provide an authentication. Another scenario level may be referred to as a “second level” scenario (or just second level). In one example the second level may include reuse of a PWB and removing an old battery cell and replacing it with a new battery cell. In other words, swapping may occur at the level of a battery pack, which may be referred to as the basic level, or at the level of one or more individual cells, which may be referred to as the second level. Other levels may also be used. Various recycling techniques as described herein may be used to protect against the different scenarios (or levels) of battery swapping, from simple protection schemes to more complicated protection schemes as described herein.

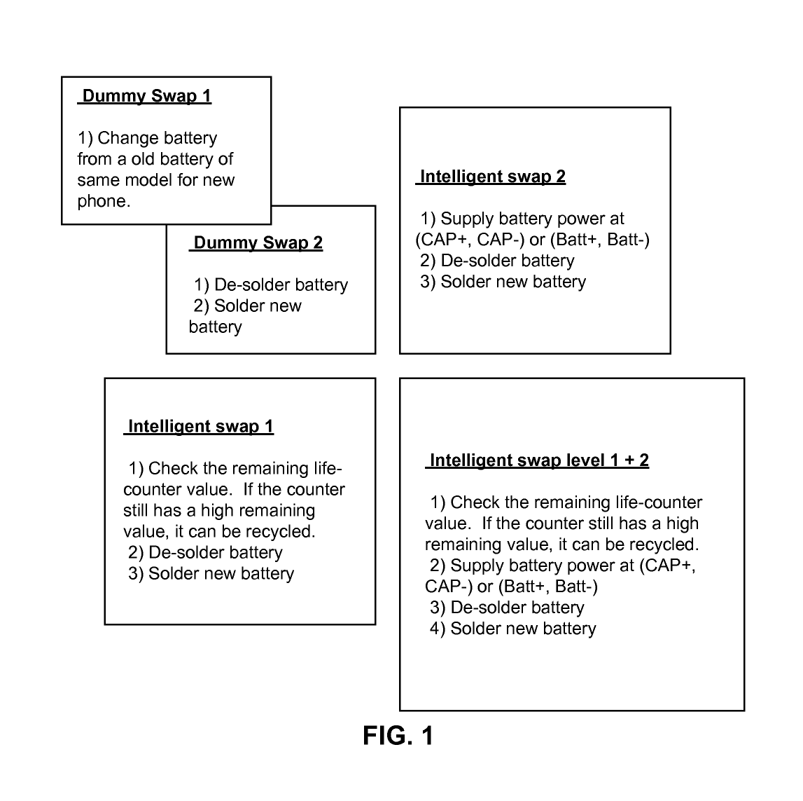

FIG. 1 is a block diagram illustrating different battery cell swapping tactics or techniques in accordance with one or more aspects of the present disclosure. Different battery cell swapping tactic have been developed through attempts to recycle by swapping battery cells. For battery systems that include battery monitoring circuitry, some battery swapping techniques may not involve any steps to determine the state of the battery monitoring circuitry. For example, it may be that no steps in such techniques are directed to checking a counter used to track the state of the battery cell(s) of the battery system or the circuitry may not monitor for battery cell swapping. Such techniques may be referred to as “dumb.” Examples include “dummy swap 1” and “dummy swap 2.” In the first example, “dummy swap 1” a battery may be charged from an old battery of the same model for a new phone. In the second example, “dummy swap 2,” an old battery may be de-soldered from a printed circuit board and a new battery may be soldered onto the printed circuit board in the old batteries place. In some examples, batteries may be spot-welded, rather than soldered. Accordingly, in some examples, an old battery may be removed from a printed circuit board and a new battery may be spot-welded onto the printed circuit board in the old batteries place.

For battery systems that include battery monitoring circuitry, some battery swapping techniques may involve steps to determine the state of the battery monitoring circuitry. Some examples may include circuitry to monitor for battery cell swapping. Such techniques may be referred to as “intelligent.” For example, a first intelligent swap example, intelligent swap 1, may check the life-count to see if the life-count that is remaining is high. In other words, some examples may read a counter that counts events related to degradation of a battery cell or battery cells to estimate how much life the battery cell(s) have left. The counter may be read to determine if the battery cell(s) have a high amount of life remaining. The old battery cell(s) may then be de-soldered or otherwise removed and the new batter cell(s) may then be solder or spot-welded to the circuit board in its place. In a second intelligent swap example, intelligent swap 2, battery power may be supplied at the battery pack terminals (Batt+, Batt−) or at the battery cell terminals (CAP+, CAP−). The old battery cell(s) may then be de-soldered or otherwise removed and the new batter cell(s) may then be solder or spot-welded to the circuit board in place of the old battery cell(s).

In another example, intelligent swap 1 and intelligent swap 2 might be combined. For example, an intelligent swap level 1 plus level 2 may check the life-count to see if the life-count remains high, battery power may be supplied to at (CAP+, CAP−) or (Batt+, Batt−). The old battery cell(s) may then be de-soldered or otherwise removed and the new battery cell(s) may then be solder or spot-welded to the circuit board in place of the old battery cell(s).

In some examples, due to safety concerns, an integrated circuit (IC) implementation on a battery printed wire board (PCB), it may be preferable that any components on the battery PCB not be powered continually or it may not be possible for the components on the battery PCB to be powered up continually. Accordingly, there may be no need to supply battery power at CAP+, CAP− or Batt+ or Batt− when replacing the battery. In some examples, the NVM counter value may be bypassed by intercepting the data value sent back to the host.

As described herein, charging capacity values, such as a nominal full charging capacity (NFCC) values may be used. In some examples, the computations to calculate charge capacity values, such as the computation used to calculate NFCC may be highly dependent on temperature. Accordingly, to accurately compare changes in charging capacity over time, temperature may have to be considered. The temperatures considered may be the entire temperature operating range of the battery. Some examples may also consider temperatures beyond the operating temperature range of the battery.

One example method of this disclosure provides a way to identify the swapping of a battery due to recycling. The example method may reduce quality and safety risks of battery use. The method may use the internal characteristic of the battery for identification and thus it may be more difficult to be substituted in a new battery cell or cells for an old battery cell or cells because the new battery cell or cells will generally have different properties from the old battery cell or battery cells. The property measured may be intrinsic to the cell itself. For example, battery (s) may have different capacity of charge storage level from battery to battery. When a battery is used, the capacity total charge that can be stored will generally change over time, charge discharge cycles, or both. Generally with each charging or discharging cycle the capacity of the cell would be slightly depleted.

When measure charging capacity over each charge/discharge cycle this capacity will generally change. This change in capacity level may allow a circuit to detect the change in variation of the capacity to decide whether the battery cell is the same battery cell (or cells) or a new battery cell (or cells) with a new capacity level (or levels). Battery cells may be measured individually or as part of a group of battery cells. If the change in NFCC per cycle charge is referred to as delta NFCC and if delta NFCC is greater that a predetermined percentage of change, the battery may be consider to be a different battery. In some examples the predetermined percentage change, delta NFCC, may be from a percentage between 1% to 20%, for example, 1%, 5%, 10%, 15%, or 20% might be used. Other values may be used in other examples.

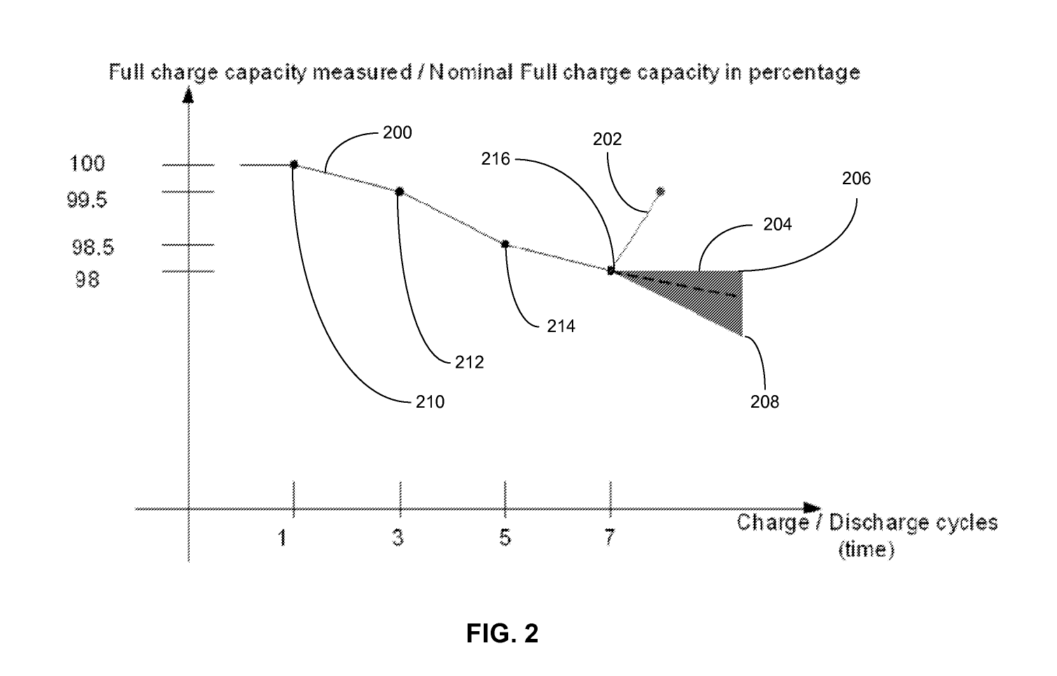

FIG. 2 is a graph illustrating an example of the trailing effect of capacity of a battery over a number of charging/discharging cycles in accordance with one or more aspects of the present disclosure. A graph line 200 of NFCC measurements 210, 212, 214, 216 at charge/discharge cycles 1, 3, 5, and 7, respectfully, for an original battery is illustrated in FIG. 2. The upward sloped line 202 illustrates how NFCC may change when a new battery cell is installed. A permitted NFCC trace region 204 illustrates an expected area region where the measured NFCC is expected to be for the original battery. Permitted NFCC trace region 204 may be based on the particular battery cell type or types being used. An upper bound 206 to permitted NFCC trace region 204 and a lower bound 208 to permitted NFCC trace region are illustrated in FIG. 2. Upper bound 206 of permitted NFCC trace region may be a horizontal line in some examples, indicating that NFCC generally does not increase as a battery cell ages or is charged and discharged. The dotted line between upper bound 206 and lower bound 208 in permitted NFCC trace region 204 indicates one possible extension to graph line 200 if a battery cell had not been replaced. In some examples, permitted NFCC trace region 204 may be a predetermined percentage. The predetermined percentage may be a function of charge/discharge cycles from a previous measurement, a function of time from a previous measurement, or a function of both charge/discharge cycles and time from a previous measurement. Furthermore, while the x-axis of FIG. 2 illustrates charge/discharge cycles as generally occurring at a periodic rate, it will be understood that the time between charge discharge cycles may vary. Additionally, time may impact charge capacity separately from charging and discharging and charging and discharging may impact capacity separate from time. Thus, permitted trace region 204 may be a function of both charge/discharge cycles and time. In some examples, battery capacity may decrease to around 50%-70% of the original capacity over 500 to 700 charge/discharge cycles. As described herein the permitted trace region may also be a function of temperature (not illustrated in FIG. 2). Accordingly, a permitted range of values for the NFCC may be a function of charge/discharge cycles, time, and temperature.

As illustrated in FIG. 2, the NFCC of the new battery, as illustrated by upward sloped line 202, does not falls within permitted region 204 expected of the battery. Accordingly, because upward sloped line 202, does not falls within the permitted region 204 expected for the battery original battery, it appears that a new battery has been. Thus, FIG. 2 provides an example of how NFCC may be used for the detection of a new battery insertion, which is when a previous battery cell or cells is removed from a circuit board including battery related circuitry and a new battery cell or cells is installed in the previous battery cell or cells place.

It will be understood that the terms “old battery,” “previous battery” may refer to any previous battery and may generally refer to the immediately prior battery installed on a circuit board because, for example, the NFCC 200 for an original battery that is compared to upward sloped line 202 may generally be for the battery immediately prior to the new battery. It will also be understood, however, that NFCC data may be stored and compared for multiple batteries in cases where multiple batteries are installed and removed from a circuit board making up part of the battery system.

In some examples, a measurement based on an existing battery may be made to determine that trailing NFCC values are observed. The test may be performed multiple times using the same test procedure and changes in NFCC level for different cells may be observed.

As described above, charging capacity values, such as a nominal full charging capacity (NFCC) values may be highly dependent on temperature. Accordingly, a series of permitted regions 204 for various temperatures may be determined based on an NFCC measurement 216 at a particular temperature. Thus, FIG. 2 may generally illustrate an example of the trailing effect of capacity of a battery over a number of charging/discharging cycles for an NFCC measurement 216 at a first temperature T₁ with a permitted region 204 also at the first temperature T₁. Other permitted values of charge capacity after measurement 216 may be determine for other temperatures.

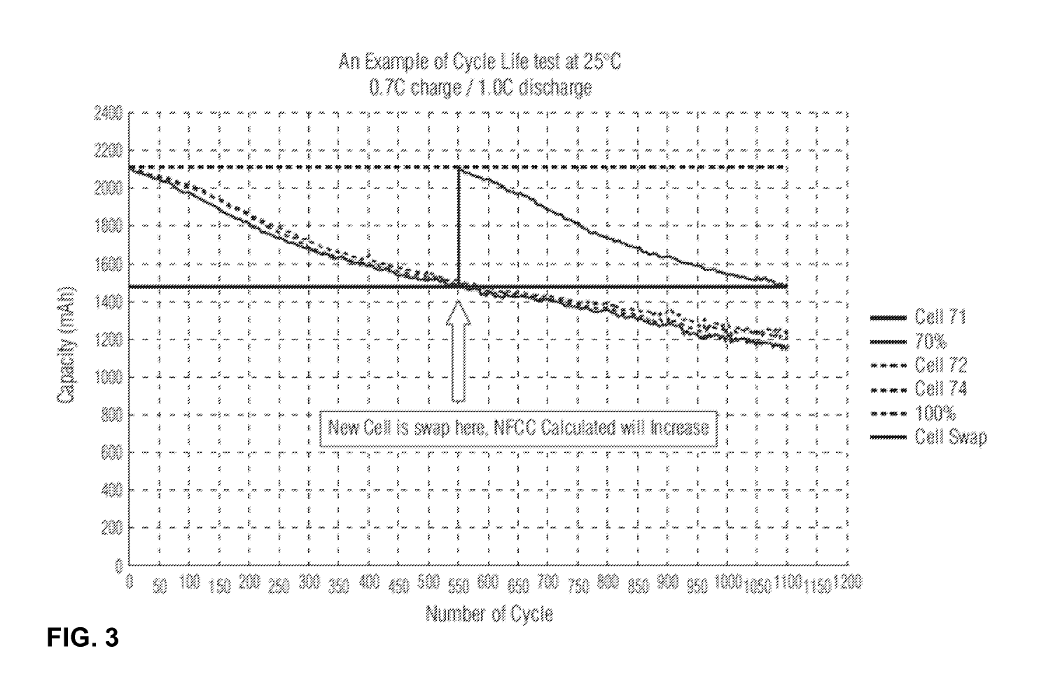

FIG. 3 is a graph illustrating an example of battery cell capacity before and after a cell swap with a cell that is inserted that has full capacity in accordance with one or more aspects of the present disclosure. FIG. 3 illustrates cells 71, 72, 74 that are measured and calculated to have a trailing path. FIG. 3 also illustrates a cell swap, where a new cell is used to replace an older cell. In the illustrated example of FIG. 3, the new cell that is inserted has full capacity, i.e., at 100%. As is illustrated in FIG. 3, cells 71, 72, and 74 each decrease in capacity over the number of cycles from 100% down to approximately 55%. The cell swap occurs at approximately 550 cycles when the capacity of the un-replaced cells is about 70%. This leads to a mismatch, with three of the cells 71, 72, and 74 at 70% capacity and dropping with continued cycles and the cell swap cell at 100% capacity and dropping with continued cycles. As illustrated, the NFCC increases with the cell swap.

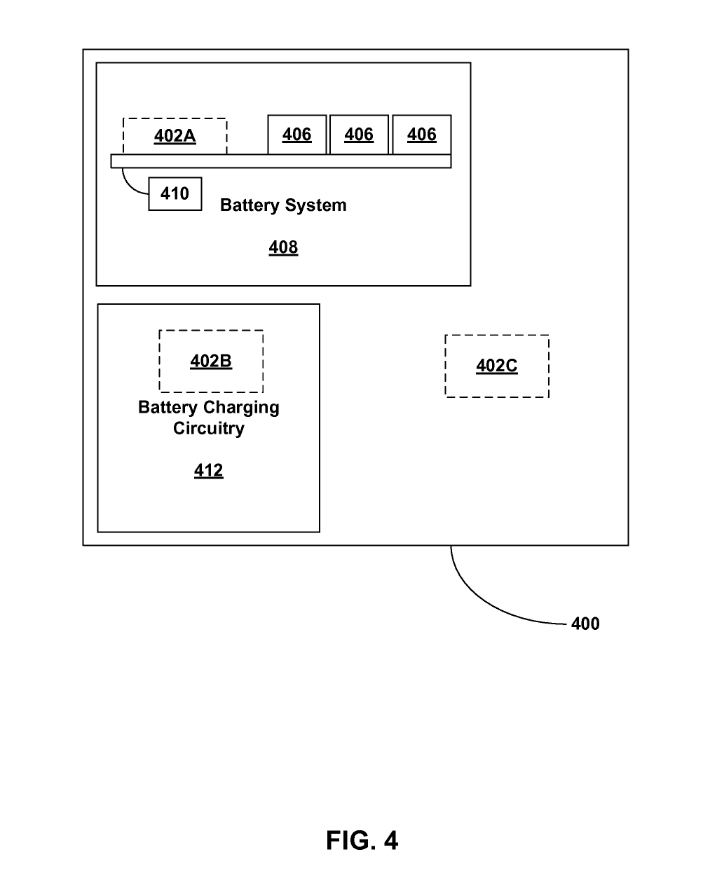

To measure capacity, the total coulomb of charges of the battery may be measured over a period of time. The charge measure may be used as a ratio to project the total capacity of the battery. This projected total capacity may be used as an indicator of the total capacity. As illustrated, the projected total capacity of the battery decreases over time. FIG. 4 is a block diagram illustrating an example electronic device 400 in accordance with one or more aspects of the present disclosure. In some examples, battery monitoring circuitry 402A, 402B, and 402C may monitor one or more batteries 404 or battery cells 406. Battery monitoring circuitry 402A may be part of a battery system 408, e.g., on a circuit board 410 on which the battery cell or cells 406 are installed. (In some examples, battery system 408 may be removable from electronic device 400.) Battery monitoring circuitry 402 may be part of battery support circuitry which may be on circuit board 410.

In some examples, battery monitoring circuitry 402B may be part of battery charging circuitry 412. In other examples, battery monitoring circuitry 402C may be part of electronic device 400 being powered by the battery cell or battery cells being monitored. Battery monitoring circuitry 402C may be on a circuit board separate from circuit board 410 that includes one or more battery cell(s) 406. Additionally, in other examples, some combination of circuitry in battery system 408, battery charging circuitry, and/or electronic device 400 being powered by the battery cell or battery cells 406 being monitored may be used to implement one or more aspects of the present disclosure.

Battery monitoring circuitry 402 may perform a first measurement on a battery cell installed in a location to determine a first NFCC. As described above, in some examples, battery monitoring circuitry 402A, 402B, and 402C may monitor one or more batteries 404 or battery cells 406. Battery monitoring circuitry 402A may be part of a battery system 408, e.g., on a circuit board 410 on which the battery cell or cells 406 are installed. In some examples, battery system 408 may be removable from electronic device 400. Battery monitoring circuitry 402 may be part of battery support circuitry which may be on circuit board 410. In some examples, the determination of an NFCC value, e.g., the first NFCC value, may be based on an NFCC calculation. The NFCC calculation may provide a measurement of capacity of the battery. The total coulombs of charge of the battery may be measured over a period of time and may be in the calculation of NFCC. The charge measurement may then be used as a ratio to project the total capacity of the battery. For example, some systems may measure the voltage across an external or internal resistance. Using the voltage across a known resistance, current may be determined. Generally, the current is approximated. The accuracy of the approximation depending on how accurately the voltage is measured and how accurately the resistance is known. The current measurement may be integrated over time to determine the total coulombs of charge into or out of the battery. Other current measuring techniques may be used in addition or in place of those described herein.

Battery monitoring circuitry 402 may determine a set of values for a permitted NFCC trace region based on the first NFCC and a number of charge/discharge cycles subsequent to performing the first measurement. The set of values will generally correspond to a set of predicted possible charge capacity values based on the number of charge/discharge cycles since a previous measurement of charge capacity, for example, values within permitted NFCC trace region 204, as illustrated with respect to FIG. 2.

Battery monitoring circuitry 402 may also perform a second measurement on a battery cell installed in the location to determine a second NFCC. As described above with respect to the measurement of the first NFCC, in some examples, the determination of an NFCC value, e.g., the second NFCC value, may be based on an NFCC calculation. The NFCC calculation may provide a measurement of capacity of the battery. The total coulombs of charge of the battery may be measured over a period of time and may be in the calculation of NFCC. The charge measurement may then be used as a ratio to project the total capacity of the battery.

Battery monitoring circuitry 402 may compare the second NFCC to the permitted NFCC trace region to determine if the second NFCC is within the set of values expected for the permitted NFCC trace region. As described above, the set of values will generally correspond to a set of predicted possible charge capacity values based on the number of charge/discharge cycles since a previous measurement of charge capacity, for example, values within permitted NFCC trace region 204, as illustrated with respect to FIG. 2.

Battery monitoring circuitry 402 may determine that the battery cell installed in the location at a time of the second measurement is the same battery cell installed in the location at the time of the first measurement when the second NFCC is a value within the set of permitted values of the NFCC trace region and that the battery cell installed in the location at the time of the second measurement is not the same battery cell installed in the location at the time of the first measurement when the second NFCC is not a value within the set of permitted values of the NFCC trace region. In other words, battery monitoring circuitry 402 may determine that a swap has occurred based on the comparison. Some example implementations may set a limit to battery cell charging, battery cell discharging, or both, based on the determination that the battery cell installed in the location at the time of the second measurement is not the same battery cell installed in the location at the time of the first measurement

In some examples, battery monitoring circuitry 402 may performing an authentication upon determining that battery cell 406 installed in the location at a time of the second measurement is not the same battery cell 406 installed in the location at the time of the first measurement to authenticate that the battery cell installed in the location at the time of the second measurement is a battery authorized by the manufacturer to be installed in the location. In one example authentication, system 402 may, upon system power up or at a periodic check, send an authentication challenge to battery cell 406. The authentication challenge may be sent within another operation of system 402. Battery cell 406 may return an authentication response to system 402, e.g., if battery cell 406 is an authentic battery, such as a battery cell 406 that is from the manufacturer. If battery cell 406 is authentic, system 402 may recognize the battery as genuine after validating the authentication response. In some examples, the challenge and response can be a single authentication step or can be a combination of multiple cycle authentication steps. The process of authentication can also be perform such that system 402 receives a stream of data from battery cell 406 encrypted by a key (or parameters) that are stored on system 402 or within an authentic battery 406. The key may only be known to, for example, the battery manufacturer. System 402 may regenerate the data stream with the key (or parameter) stored in system 402 and check to determine that the data matches to determine that the battery 406 is genuine. This is one example authentication. Other authentication methods may also be used to determine if a batter cell 406 is authentic.

In some examples, battery monitoring circuitry 402 may reset battery monitoring circuitry upon determining that the battery cell installed in the location at a time of the second measurement is not the same battery cell installed in the location at the time of the first measurement. In some examples, the example battery monitoring circuitry may reset the battery monitoring circuitry only occurs when the battery cell installed in the location at the time of the second measurement is a battery authorized by the manufacturer to be installed in the location.

In some examples, the example battery monitoring circuitry may notify a user based on the determination that the battery cell installed in the location at the time of the second measurement is not the same battery cell installed in the location at the time of the first measurement.

In some examples, the example battery monitoring circuitry may disable a mobile device in which the battery that is being monitored is installed based on the determination that the battery cell installed in the location at the time of the second measurement is not the same battery cell installed in the location at the time of the first measurement.

In some examples, the example battery monitoring circuitry may send a message to a service center based on the determination that the battery cell installed in the location at the time of the second measurement is not the same battery cell installed in the location at the time of the first measurement.

In some examples, the example battery monitoring circuitry may set a flag based on the determination that the battery cell installed in the location at the time of the second measurement is not the same battery cell installed in the location at the time of the first measurement.

In some examples, the example battery monitoring circuitry may save an indication in a memory when the determination that the battery cell installed in the location at the time of the second measurement is not the same battery cell installed in the location at the time of the first measurement is made.

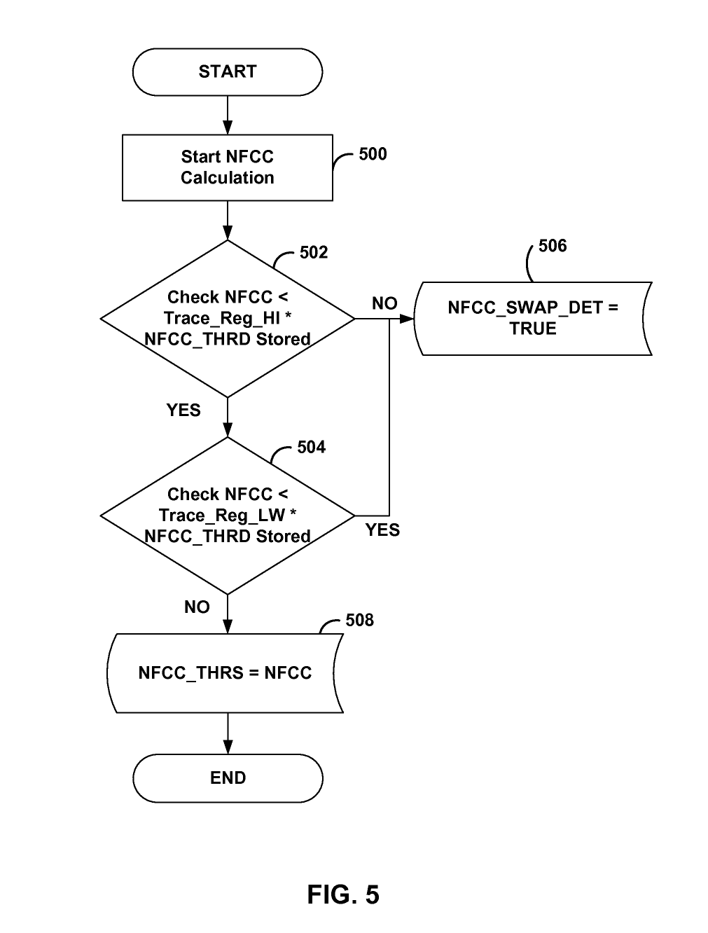

FIG. 5 is a flowchart illustrating an example method for detection of battery monitoring circuitry recycling, in accordance with one or more aspects of the present disclosure. In some examples, the example method may be implemented in the battery monitoring circuitry 402 illustrated in FIG. 4. In the example of FIG. 5, the variable NFCC indicates the most recently measured or calculated NFCC value. The variable NFCC_THRS indicates a stored NFCC value from an earlier measured NFCC value. For example, referring back to FIG. 2, graph line 200 of NFCC measurements 210, 212, 214, 216 at charge/discharge cycles 1, 3, 5, and 7, respectfully, if the variable NFCC indicates a measurement 214 of NFCC at charge/discharge cycle 5 in FIG. 2, NFCC_THRS might be a stored earlier measurement 212 of NFCC from charge/discharge cycle 3 in FIG. 2.

Additionally, in the example of FIG. 5, the variable Trace_Reg_HI indicates a function of charge/discharge cycle, time, or both, that may be used to determine an upper boundary 206 for permitted NFCC trace region 204. Trace_Reg_LW indicates a function of charge/discharge cycle, time, or both, that may be used to determine a lower boundary 208 for permitted NFCC trace region 204.

As illustrated in the example method of FIG. 5, battery monitoring circuitry 402 may estimate the flow on the detection of the battery recycling. Battery monitoring circuitry 402 starts an NFCC calculation. In some examples, an NFCC measurement may be performed as part of the NFCC calculation (500).

In the illustrated example of FIG. 5, after each completed calculation of NFCC, battery monitoring circuitry 402 may perform a check to determine if the calculated NFCC value is lower than the previous NFCC value, which may be stored in a memory. For example, after each completed calculation of NFCC, battery monitoring circuitry 402 may compare an NFCC measurement or NFCC calculation to a permitted NFCC trace region 204.

The NFCC may be compared to the product of Trace_Reg_HI*NFCC_THRS to determine if NFCC is less than the product of NFCC_THRS*Trace_Reg_HI (502). The high boundary illustrated, i.e., Trace_Reg_hi, may be near a value of “1,” but is generally not equal to 1 because most implementations may provide some margin for error in the computation of NFCC_THRS or variations in measurements due to, e.g., instrumentation variation. Additionally, in some examples, NFCC_THRS may be a previously measured NFCC with some amount added to provide some margin for measurement or instrumentation variations. The product of Trace_Reg_HI*NFCC_THRS provides the upper boundary 206 of permitted NFCC trace region 204. As described above, NFCC_THRS may be a previously measured NFCC value and the value Trace_Reg_HI may be a function of the number of charge/discharge cycles the battery cell being tested has experienced. Trace_Reg_HI may provide a multiplier that may be used to estimate or provide the upper boundary 206 of permitted NFCC trace region 204. If a measured or calculated NFCC value is greater than NFCC_THRS*Trace_Reg_HI, the estimated upper boundary 206 of permitted NFCC trace region 204, this may be an indication that a new cell has been swapped on an existing old PCB. Furthermore, if an NFCC value is greater than NFCC_THRS*Trace_Reg_HI or, said another way, when NFCC is not less than NFCC_THRS*Trace_Reg_HI the NFCC value is above the upper boundary 206 of permitted NFCC trace region 204 and NFCC_SWAP_DET may be set to “true” (506).

NFCC_SWAP_DET may be a logical variable. Logical variables may be set to “true” or “false.” In some examples, “true” may be a logical “1” or “high” in an active high logic implementation or “true” may be represented by a logical “0” or “low” in an active low logic implementation. It will be understood that the use of either a higher voltage or a lower voltage level to represent either logic state is arbitrary. For example, a higher voltage, e.g., approximately 2 to 5 volts in transistor-transistor logic (TTL), may represent a logic “1” value for an active high implementation and a lower voltage, e.g., approximately 0 to 0.8 volts in TTL, may represent a logic “0.” However, in an active low example, a higher voltage, may represent a logic “0” value and a lower voltage may represent a logic “1.”

If NFCC is less than NFCC_THRS*Trace_Reg_HI, this indicates that NFCC is below the upper boundary 206 of permitted NFCC trace region 204 and may fall within or below permitted NFCC trace region 204. Accordingly, if NFCC is less than NFCC_THRS*Trace_Reg_HI, battery monitoring circuitry 402 checks whether NFCC is greater than NFCC_THRS*Trace_Reg_LW (504). NFCC_THRS*Trace_Reg_LW may be used to determine the lower boundary 208 of permitted NFCC trace region 204. As described above, Trace_Reg_LW may be a function of number of charge/discharge cycles the cell has experience, time, or both charge/discharge cycles and time.

When NFCC is less than NFCC_THRS*Trace_Reg_HI and NFCC is higher than NFCC_THRS*Trace_Reg_LW, this indicated that a new cell which has a much lower capacity has been swapped on an existing old PCB.

Based on the comparison of NFCC and NFCC_THRS*Trace_Reg_LW (504), when NFCC is less than NFCC_THRS*Trace_Reg_HI and NFCC is lower than NFCC_THRS*Trace_Reg_LW, this indicates that the measured NFCC value is below permitted NFCC trace region 204 and it is likely that a new cell which has a much lower capacity has been swapped on an existing PCB and NFCC_SWAP_DET may be set to “true” (506). When NFCC is less than NFCC_THRS*Trace_Reg_HI and NFCC is higher than NFCC_THRS*Trace_Reg_LW, this indicated that the measured NFCC value is within permitted NFCC trace region 204 and at the end of each computation, battery monitoring circuitry 402 may update the value of NFCC_THRS with the newly measured NFCC value (508).

Full charge capacity is discussed in the Smart Battery Data Specification, Revision 1.1, Dec. 11, 1998, and as of May 19, 2014 available at http://sbs-forum.org/specs/sbdat110.pdf under 5.1.17. As discussed therein, a function, FullChargeCapacity( ) (0x10) provides capacity data information that may be used in conjunction with one or more aspects of the present disclosure.

For example, the FullChargeCapacity( ) (0x10) function returns the predicted battery pack capacity when it is fully charged. The FullChargeCapacity( ) value may be expressed in current (e.g., mAh at a C/5 discharge rate) or power (e.g., 10 mWh at a P/5 discharge rate) depending on the battery mode setting for a capacity mode bit. One purpose for the FullChargeCapacity( ) function is to provide a user with a means of understanding the “tank size” of a battery. This information, along with information about the original capacity of the battery, may be presented to the user as an indication of battery wear.

The output may be an unsigned integer that is an estimated full charge capacity in, e.g., mAh or 10 mWh. It will be understood estimates may be made for one or more cells of a battery pack. In some examples in accordance with one or more aspects of the present disclosure, individual battery cells may be monitored to determine if one or more of the individual cells have been changed. In other examples, over all capacity of a group of cells may be monitored to determine if one or more of the battery cells within the group have been changed. Some battery systems may include one cell, one group of cells, or multiple groups of battery cells. In accordance with one or more aspects of the present disclosure cells may be monitored at the individual battery cell level or at a battery cell group level.

A product including the FullChargeCapacity( ) function that may be used to estimate the nominal full charge capacity parameter to detect battery swapping, i.e., one or more battery cells being changed or swapped for a different battery cell or battery cells, thus providing additional enhancement for monitoring the battery swapping issue. Battery swapping is a problem and the authentication solution described herein with life-count does not fully cover detection, accordingly, additional features described herein may be used.

One other internal battery characteristic that may be monitored and can be of use is the internal impedance of the battery. However, the impedance changes in term of current and cycles of charging may be much harder to be used reliably as a method for detecting battery swapping and used as a form of identification.

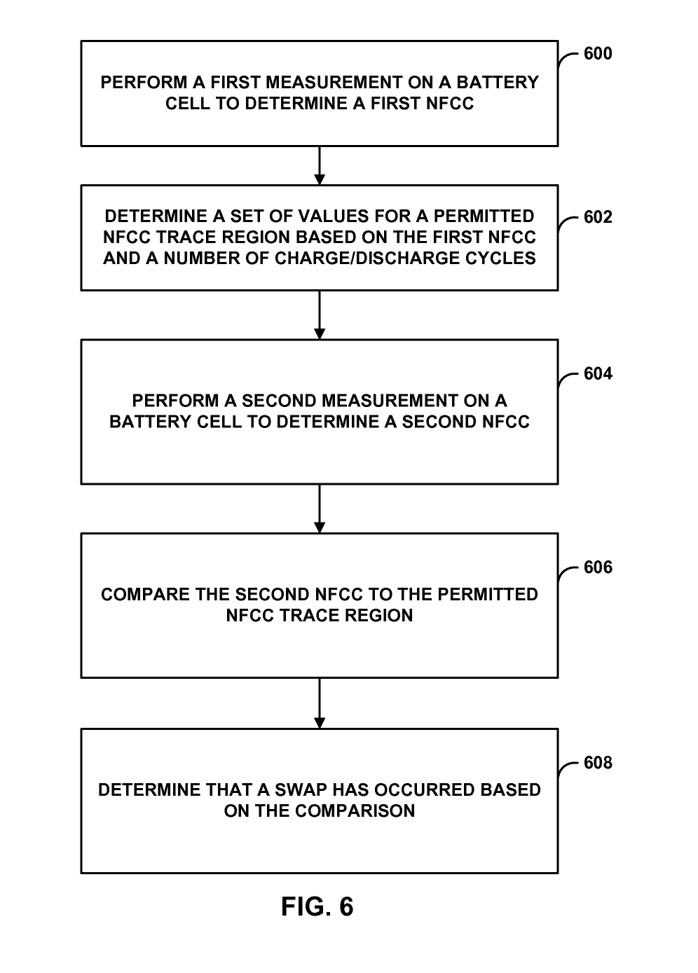

FIG. 6 is another flowchart illustrating an example method for detection of battery monitoring circuitry recycling, in accordance with one or more aspects of the present disclosure. Battery monitoring circuitry 402 may perform a first measurement on a battery cell installed in a location to determine a first NFCC (600). As described above, in some examples, battery monitoring circuitry 402A, 402B, and 402C may monitor one or more batteries 404 or battery cells 406. Battery monitoring circuitry 402A may be part of a battery system 408, e.g., on a circuit board 410 on which the battery cell or cells 406 are installed. In some examples, battery system 408 may be removable from electronic device 400. Battery monitoring circuitry 402 may be part of battery support circuitry which may be on circuit board 410. In some examples, the determination of an NFCC value, e.g., the first NFCC value, may be based on an NFCC calculation. The NFCC calculation may provide a measurement of capacity of the battery. The total coulombs of charge of the battery may be measured over a period of time and may be in the calculation of NFCC. The charge measurement may then be used as a ratio to project the total capacity of the battery.

Battery monitoring circuitry 402 may determine a set of values for a permitted NFCC trace region based on the first NFCC and a number of charge/discharge cycles subsequent to performing the first measurement (602). The set of values will generally correspond to a set of predicted possible charge capacity values based on the number of charge/discharge cycles since a previous measurement of charge capacity, for example, values within permitted NFCC trace region 204, as illustrated with respect to FIG. 2.

Battery monitoring circuitry 402 may also perform a second measurement on a battery cell installed in the location to determine a second NFCC (604). As described above with respect to the measurement of the first NFCC, in some examples, the determination of an NFCC value, e.g., the second NFCC value, may be based on an NFCC calculation. The NFCC calculation may provide a measurement of capacity of the battery. The total coulombs of charge of the battery may be measured over a period of time and may be in the calculation of NFCC. The charge measurement may then be used as a ratio to project the total capacity of the battery.

Battery monitoring circuitry 402 may compare the second NFCC to the permitted NFCC trace region (606) to determine if the second NFCC is within the set of values expected for the permitted NFCC trace region. As described above, the set of values will generally correspond to a set of predicted possible charge capacity values based on the number of charge/discharge cycles since a previous measurement of charge capacity, for example, values within permitted NFCC trace region 204, as illustrated with respect to FIG. 2.

Battery monitoring circuitry 402 may determine that the battery cell installed in the location at the time of the second measurement is the same battery cell installed in the location at the time of the first measurement when the second NFCC is a value within the set of permitted values of the NFCC trace region and that the battery cell installed in the location at the time of the second measurement is not the same battery cell installed in the location at the time of the first measurement when the second NFCC is not a value within the set of permitted values of the NFCC trace region. In other words, battery monitoring circuitry 402 may determine that a swap has occurred based on the comparison (608). Some example implementations may set a limit to battery cell charging, battery cell discharging, or both, based on the determination that the battery cell installed in the location at the time of the second measurement is not the same battery cell installed in the location at the time of the first measurement.

Some examples in accordance with one or more aspects of the present disclosure relate to a non-transitory computer readable storage medium storing instructions that upon execution by one or more processors cause the one or more processors to perform a first measurement on a battery cell installed in a location to determine a first NFCC, determine a set of values for a permitted NFCC trace region based on the first NFCC and a number of charge/discharge cycles subsequent to performing the first measurement, perform a second measurement on a battery cell installed in the location to determine a second NFCC, compare the second NFCC to the permitted NFCC trace region, and determine that the battery cell installed in the location at a time of the second measurement is the same battery cell installed in the location at the time of the first measurement when the second NFCC is a value within the set of values for a permitted NFCC trace region and that the battery cell installed in the location at a time of the second measurement is not the same battery cell installed in the location at the time of the first measurement when the second NFCC is not a value within the set of values for a permitted NFCC trace region.

For example, a computer-readable storage medium may form part of a computer program product, which may include packaging materials. A computer-readable storage medium may comprise a computer data storage medium such as random access memory (RAM), synchronous dynamic random access memory (SDRAM), read-only memory (ROM), non-volatile random access memory (NVRAM), electrically erasable programmable read-only memory (EEPROM), FLASH memory, magnetic or optical data storage media, and the like. A computer-readable storage medium may comprise a non-transitory computer data storage medium. The techniques additionally, or alternatively, may be realized at least in part by a computer-readable communication medium that carries or communicates code in the form of instructions or data structures and that can be accessed, read, and/or executed by a computer. The computer readable storage medium may store instructions that upon execution by one or more processors cause the one or more processors to perform one or more aspects of this disclosure.

The code or instructions may be executed by one or more processors, such as one or more DSPs, general purpose microprocessors, ASICs, field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated software modules or hardware modules. The disclosure also contemplates any of a variety of integrated circuit devices that include circuitry to implement one or more of the techniques described in this disclosure. Such circuitry may be provided in a single integrated circuit chip or in multiple, interoperable integrated circuit chips in a so-called chipset. Such integrated circuit devices may be used in a variety of applications.

Various examples have been described. These and other examples are within the scope of the following claims.

What is claimed is:

1. A method of battery monitoring comprising:
performing a first measurement on a battery cell installed in a location to determine a first charging capacity;
determining a set of values for a permitted charging capacity trace region based on the first charging capacity and a number of charge/discharge cycles subsequent to performing the first measurement;
performing a second measurement on a battery cell installed in the location to determine a second charging capacity;
comparing the second charging capacity to the permitted charging capacity trace region; and
determining that the battery cell installed in the location at a time of the second measurement is the same battery cell installed in the location at the time of the first measurement when the second charging capacity is a value within the set of values for a permitted charging capacity trace region and that the battery cell installed in the location at a time of the second measurement is not the same battery cell installed in the location at the time of the first measurement when the second charging capacity is not a value within the set of values for a permitted charging capacity trace region.

2. The method of claim 1, further comprising performing an authentication upon determining that the battery cell installed in the location at the time of the second measurement is not the same battery cell installed in the location at the time of the first measurement to authenticate that the battery cell installed in the location at the time of the second measurement is a battery authorized by the manufacturer to be installed in the location.

3. The method of claim 1, reset battery monitoring circuitry upon determining that the battery cell installed in the location at the time of the second measurement is not the same battery cell installed in the location at the time of the first measurement.

4. The method of claim 3, wherein resetting the battery monitoring circuitry only occurs when the battery cell installed in the location at the time of the second measurement is a battery authorized by the manufacturer to be installed in the location.

5. The method of claim 1, further comprising notifying a user based on the determination that the battery cell installed in the location at the time of the second measurement is not the same battery cell installed in the location at the time of the first measurement.

6. The method of claim 1, further comprising disabling a mobile device in which the battery that is being monitored is installed based on the determination that the battery cell installed in the location at the time of the second measurement is not the same battery cell installed in the location at the time of the first measurement.

7. The method of claim 1, further comprising sending a message to a service center based on the determination that the battery cell installed in the location at the time of the second measurement is not the same battery cell installed in the location at the time of the first measurement.

8. The method of claim 1, further comprising setting a flag based on the determination that the battery cell installed in the location at the time of the second measurement is not the same battery cell installed in the location at the time of the first measurement, the method further comprising setting a limit to battery cell charging, battery cell discharging, or both, based on the determination that the battery cell installed in the location at the time of the second measurement is not the same battery cell installed in the location at the time of the first measurement.

9. The method of claim 1, further comprising saving an indication in a memory upon determining that the battery cell installed in the location at the time of the second measurement is not the same battery cell installed in the location at the time of the first measurement.

10. A device for battery monitoring comprising:
a battery monitoring circuitry;
a memory;
a processor, coupled to the memory and configured to:
perform a first measurement on a battery cell installed in a location to determine a first charging capacity;
determine a set of values for a permitted charging capacity trace region based on the first charging capacity and a number of charge/discharge cycles subsequent to performing the first measurement;
perform a second measurement on a battery cell installed in the location to determine a second charging capacity;
compare the second charging capacity to the permitted charging capacity trace region; and
determine that the battery cell installed in the location at a time of the second measurement is the same battery cell installed in the location at the time of the first measurement when the second charging capacity is a value within the set of values for a permitted charging capacity trace region and that the battery cell installed in the location at a time of the second measurement is not the same battery cell installed in the location at the time of the first measurement when the second charging capacity is not a value within the set of values for a permitted charging capacity trace region.

11. The device of claim 10, wherein the processor is further configured to perform an authentication upon determining that the battery cell installed in the location at the time of the second measurement is not the same battery cell installed in the location at the time of the first measurement to authenticate that the battery cell installed in the location at the time of the second measurement is a battery authorized by the manufacturer to be installed in the location.

12. The device of claim 10, wherein the processor is further configured to reset battery monitoring circuitry upon determining that the battery cell installed in the location at the time of the second measurement is not the same battery cell installed in the location at the time of the first measurement.

13. The device of claim 12, wherein the device resets the battery monitoring circuitry only when the battery cell installed in the location at the time of the second measurement is a battery authorized by the manufacturer to be installed in the location.

14. The device of claim 10, wherein the processor is further configured to notify a user based on the determination that the battery cell installed in the location at the time of the second measurement is not the same battery cell installed in the location at the time of the first measurement.

15. The device of claim 10, wherein the processor is further configured to disable a mobile device in which the battery that is being monitored is installed based on the determination that the battery cell installed in the location at the time of the second measurement is not the same battery cell installed in the location at the time of the first measurement.

16. The device of claim 10, wherein the processor is further configured to send a message to a service center based on the determination that the battery cell installed in the location at the time of the second measurement is not the same battery cell installed in the location at the time of the first measurement.

17. The device of claim 10, wherein the processor is further configured to set a flag based on the determination that the battery cell installed in the location at the time of the second measurement is not the same battery cell installed in the location at the time of the first measurement, and the processor is further configured to set a limit to battery cell charging, battery cell discharging, or both, based on the determination that the battery cell installed in the location at the time of the second measurement is not the same battery cell installed in the location at the time of the first measurement.

18. The device of claim 10, wherein the processor is further configured to save an indication in the memory upon determining that the battery cell installed in the location at the time of the second measurement is not the same battery cell installed in the location at the time of the first measurement.

19. The device of claim 10, wherein the battery monitoring circuitry is part of a battery system and on a circuit board including at least one battery cell or wherein the battery monitoring circuitry is on a circuit board separate from the circuit board including the at least one battery cell.

20. A device for battery monitoring comprising:
means for performing a first measurement on a battery cell installed in a location to determine a first charging capacity;
means for determining a set of values for a permitted charging capacity trace region based on the first charging capacity and a number of charge/discharge cycles subsequent to performing the first measurement;
means for performing a second measurement on a battery cell installed in the location to determine a second charging capacity;
means for comparing the second charging capacity to the permitted charging capacity trace region; and
means for determining that the battery cell installed in the location at a time of the second measurement is the same battery cell installed in the location at the time of the first measurement when the second charging capacity is a value within the set of values for a permitted charging capacity trace region and that the battery cell installed in the location at a time of the second measurement is not the same battery cell installed in the location at the time of the first measurement when the second charging capacity is not a value within the set of values for a permitted charging capacity trace region.
